(19) United States
(12) Patent Application Publication
(10) Pub. No.: US 2019/0050363 A1
(43) Pub. Date: Feb. 14, 2019

(54) ELECTRONIC DEVICE, LOGIC CHIP AND COMMUNICATION METHOD OF LOGIC CHIP

(71) Applicant: Chun-Hsuan Li, Taipei City (TW)

(72) Inventor: Chun-Hsuan Li, Taipei City (TW)

(73) Assignee: COMPAL ELECTRONICS, INC., Taipei City (TW)

(21) Appl. No.: 16/102,762

(22) Filed: Aug. 14, 2018

Related U.S. Application Data
(60) Provisional application No. 62/545,437, filed on Aug. 14, 2017.

(51) Int. Cl. G06F 13/40; H03K 19/0175

(52) U.S. Cl. CPC G06F 13/4068; H03K 19/017509

(57) ABSTRACT

An electronic device, a logic chip and a communication method of the logic chip are provided. The electronic device includes a connection port, a processor and the logic chip. The connection port is coupled to a peripheral device and the processor is coupled to the connection port. The logic chip has a plurality of interface modes, and includes a first communication interface, a second communication interface and a logic circuit. The first communication interface is coupled to the processor. The second communication interface is coupled to the connection port. The logic circuit is coupled between the first and second communication interfaces and makes the logic chip operate in the interface mode corresponding to the connection port according to a predetermined mode signal. The processor communicates with the peripheral device through the logic chip operating in the interface mode corresponding to the connection port and the connection port.

### CROSS-REFERENCE TO RELATED APPLICATION

This application claims the priority benefit of U.S. provisional application Ser. No. 62/545,437, filed on Aug. 14, 2017. The entirety of the above-mentioned patent application is hereby incorporated by reference herein and made a part of this specification.

### BACKGROUND OF THE INVENTION

### Field of the Invention

The invention relates to a communication technology, and particularly relates to an electronic device, a logic chip, and a communication method of a logic chip.

### Description of Related Art

As science and technology advance, electronic devices need to be connected with various peripheral devices having different communication protocols, such as keyboards, mice, etc. Therefore, various communication interfaces are provided to support these peripheral devices of different types. However, various circuits are designed between the communication interfaces and the processors of the electronic devices in order to cope with different types of communication interfaces.

FIG. 1 is a schematic block diagram illustrating communication between an electronic device and a peripheral device according to the known art. As shown in FIG. 1, an electronic device 100 may be coupled to a plurality of peripheral devices 210, 220, 230, and 240 having different communication specifications. For example, the electronic device 100 is coupled to the peripheral device 210 through an inter-integrated circuit (I²C) bus interface, coupled to the peripheral device 220 through a cathode ray tube (CRT) interface, coupled to the peripheral device 230 through a display port (DP), and coupled to the peripheral device 240 through a high definition multimedia interface (HDMI). To comply with data transmissions under different communication protocols, the processor 110 of the electronic device 100 are electrically connected with the peripheral devices 210 to 240 by using different logic chips 120, 130, 140, and 150. These logic chips 120, 130, 140, and 150 respectively have their own circuit designs and components. Therefore, the number of components on a printed circuit board (PCB) may easily increase, and the circuit layout may be complicated.

### SUMMARY OF THE INVENTION

Embodiments of the invention provide an electronic device, a logic chip, and a communication method of a logic chip. The logic chip has a plurality of interface modes and is able to support connection ports of different types, thereby offering favorable compatibility. Therefore, the electronic device using the logic chip has a simplified circuit design as well as a reduced cost.

An embodiment of the invention provides an electronic device. The electronic device is electrically connected to a peripheral device and includes a connection port, a processor, and a logic chip. The connection port is configured to be coupled to a peripheral device and the processor is coupled to the connection port. The logic chip has a plurality of interface modes, and includes a first communication interface, a second communication interface and a logic circuit. The first communication interface is coupled to the processor. The second communication interface is coupled to the connection port. The logic circuit is coupled between the first communication interface and the second communication interface. The logic circuit makes the logic chip operate in one of the interface modes corresponding to the connection port according to a predetermined mode signal. The processor communicates with the peripheral device through the logic chip operating in the interface mode and the connection port.

An embodiment of the invention provides a logic chip. The logic chip is suitable for an electronic device. The electronic device includes a processor and a connection port. The connection port is electrically connected to a peripheral device. The logic chip includes a first communication interface coupled to the processor, a second communication interface coupled to the connection port, and a logic circuit. The logic circuit is coupled between the first communication interface and the second communication interface. The logic chip has a plurality of interface modes. The logic circuit makes the logic chip operate in one of the interface modes corresponding to the connection port according to a predetermined mode signal. The processor communicates with the peripheral device through the logic chip operating in the interface mode and the connection port.

An embodiment of the invention provides a communication method of a logic chip. The communication method is suitable for an electronic device. The electronic device includes a connection port, a processor, and a logic chip. In addition, the connection port is electrically connected to a peripheral device and the logic chip, the logic chip is coupled to the processor, and the logic chip has a plurality of interface modes and a logic circuit. The communication method includes the following. A predetermined mode signal is determined in advance according to the connection port to which the logic chip is connected. The logic chip operates in one interface mode of the interface modes corresponding to the connection port according to the predetermined mode signal. In addition, the processor communicates with the peripheral device through the logic chip operating in the interface mode and the connection port.

Based on the above, in the electronic device, the logic chip, and the communication method of the logic chip according to the embodiments of the invention, the logic chip has multiple interface modes capable of supporting communication protocols of different types. Therefore, different types of connection ports may be electrically connected to the same logic chips in the electronic device. Therefore, the internal circuits can be integrated, and the layout space of the circuit board can be reduced.

In order to make the aforementioned and other features and advantages of the invention comprehensible, several exemplary embodiments accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic block diagram illustrating communication between an electronic device and a peripheral device according to the known art.

FIG. 2 is a block diagram illustrating an electronic device according to an embodiment of the invention.

FIG. 3 is a block diagram illustrating a circuit of a logic chip according to an embodiment of the invention.

FIG. 4 is a schematic circuit diagram illustrating a logic chip in a first interface mode according to an embodiment of the invention.

FIG. 5 is a flowchart illustrating a communication method of a logic chip according to an embodiment of the invention.

### DESCRIPTION OF THE EMBODIMENTS

Reference will now be made in detail to the present preferred embodiments of the invention, examples of which are illustrated in the accompanying drawings.

Wherever possible, the same reference numbers are used in the drawings and the description to refer to the same or like parts.

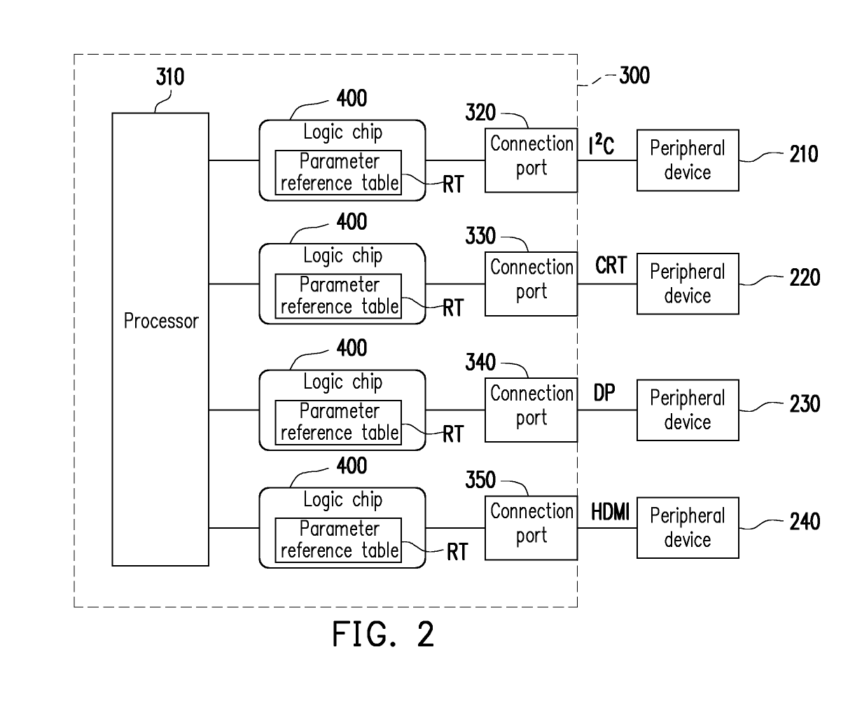

FIG. 2 is a block diagram illustrating an electronic device according to an embodiment of the invention. Referring to FIG. 2, an electronic device 300 includes a processor 310, at least one connection port, and a logic chip 400 coupled between the connection port and the processor 310. The connection port is adapted to electrically connect a peripheral device. In this embodiment, four connection ports 320, 330, 340, and 350 are respectively connected with peripheral devices 210, 220, 230, and 240 of different types. The connection port 320 is an I²C communication interface, and the peripheral device 210 is, for example, a touch pad, a fingerprint recognizer, a sensor, etc. The connection port 330 is a CRT communication interface, and the peripheral device 220 is a CRT display, for example. The connection port 340 is a DP communication interface, and the connection port 350 is an HDMI communication interface. The peripheral devices 230 and 240 may be liquid crystal displays or the like, for example. Therefore, the electronic device 300 may communicate with the peripheral devices 210 to 240 through the logic chips 400 and the connection ports 320 to 350. In the embodiment, one logic chip is connected to one connection port and one peripheral device. However, in another embodiment, one logic chip may be connected to multiple connection ports and multiple peripheral devices. In addition, the invention does not intend to limit the numbers and the types of the connection ports and the peripheral devices.

The logic chip 400 includes a memory (not shown herein) for storing a parameter reference table RT. The logic chip 400 may operate in a corresponding interface mode according to the connection port (one of the connection ports 320, 330, 340, and 350) to which the logic chip 400 is connected. For example, the logic chip 400 connected to the connection port 320 may determine that the connection port 320 is an I²C communication interface and therefore the logic chip 400 may switch to an interface mode suitable for I²C communication. In this way, the processor 310 can transmit I²C signals to the peripheral device 210 through the logic chip 400. Embodiments of the logic chip 400 will be described in detail in the following.

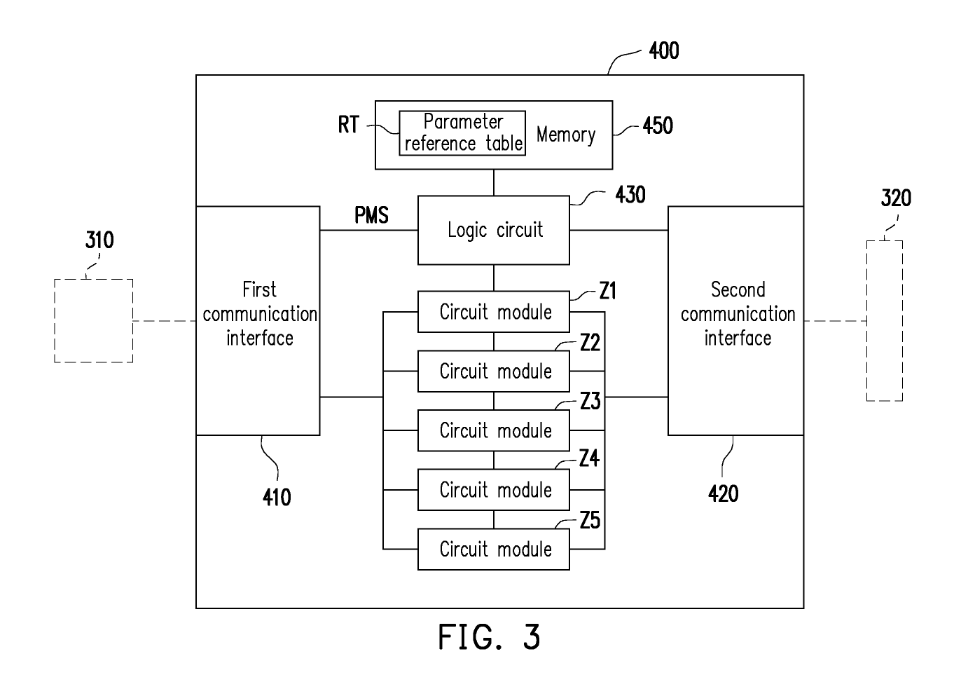

FIG. 3 is a block diagram illustrating a circuit of a logic chip according to an embodiment of the invention. Referring to FIGS. 2 and 3, the logic chip 400 further includes a first communication interface 410, a second communication interface 420, a logic circuit 430, a memory 450, and a plurality of circuit modules. In this embodiment, the number of the circuit module is five, i.e., the circuit modules Z1 to Z5. The logic circuit 430 is coupled to the processor 310 through the first communication interface 410, and is coupled to one of the connection ports 320 to 350 through the second communication interface 420. In FIG. 3, the connection port 320 is shown as an example. The circuit modules Z1 to Z5 are coupled to the logic circuit 430, the first communication interface 410, and the second communication interface 420.

The logic chip 400 has a plurality of interface modes. In the embodiment, the number of the interface mode is four. The four interface modes are a first interface mode (the I²C mode, for example), a second interface mode (the CRT mode, for example), a third interface mode (the DP mode, for example), and a fourth interface mode (the HDMI mode, for example). The logic circuit 430 is further coupled to the memory 450. The memory 450 stores the parameter reference table RT. The parameter reference table RT records a corresponding relationship between a predetermined mode signal PMS and the interface modes. The predetermined mode signal PMS is configured in advance according to the connection port to which the logic chip 400 is connected. When the connection port to which the logic chip 400 is connected remains the same, the predetermined mode signal PMS also remains the same. According to the predetermined mode signal PMS, the logic circuit 430 may determine the interface mode corresponding to the connection port through the parameter reference table RT.

More specifically, the circuit modules Z1 to Z5 may be individually enabled or disabled by the logic chip 400 according to the predetermined mode signal PMS, so that the logic chip 400 can operate in one of the interface modes. For example, in an assembling process, the communication type of the connection port to which the logic chip 400 is about to electrically connect is already known. Therefore, the predetermined mode signal PMS with the corresponding setting in advance can be input into the logic chip 400. In the following, an embodiment will be described to explain in detail the operation of the logic chip 400.

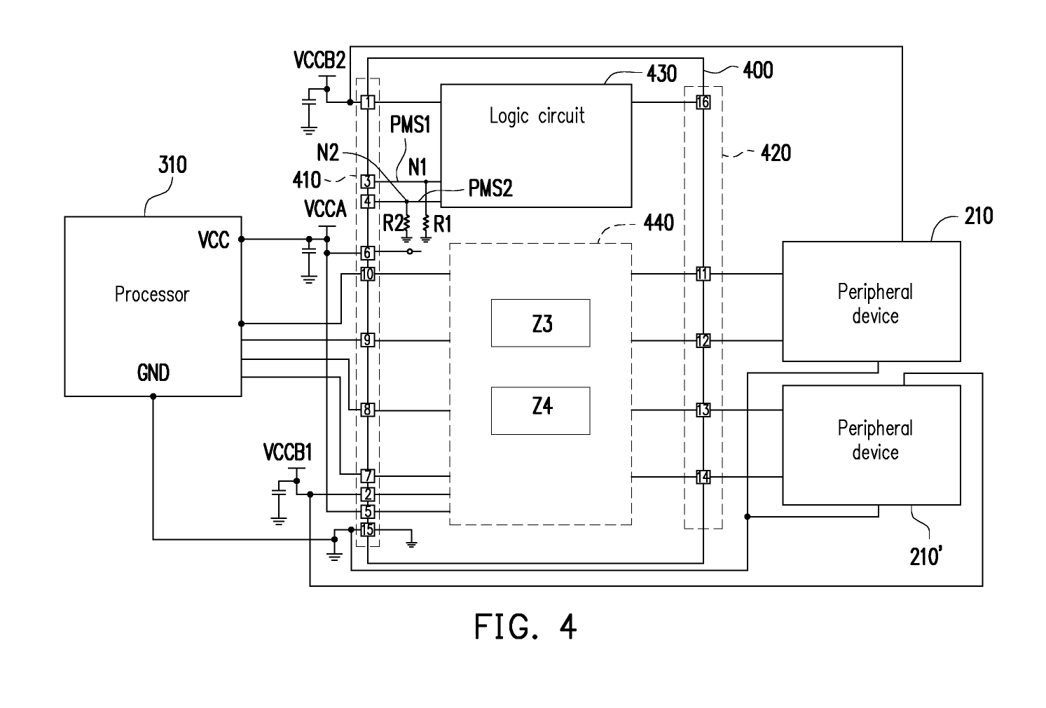

FIG. 4 is a schematic circuit diagram illustrating a logic chip in a first interface mode according to an embodiment of the invention. Referring to FIGS. 2, 3, and 4, the logic chip 400 is connected to two peripheral devices 210 and 210′ through two I²C connection ports (not shown herein). The electronic device 300 may provide a plurality of reference voltages VCC, VCCA, VCCB1, and VCCB2, and a ground voltage GND. The reference voltages VCC, VCCA, VCCB1, and VCCB2 are 3V or 5V, for example, and may be the same as or different from each other. The reference voltages VCC, VCCA, VCCB1, and VCCB2 are merely described above as an example. The invention does not intend to impose a limitation on the reference voltages.

The logic chip 400 further includes a first mode detecting node N1 and a second mode detecting node N2, which are coupled to the logic circuit 430, as well as a first resistor R1 and a second resistor R2. The predetermined mode signal PMS includes a first mode signal PMS1 and a second mode signal PMS2. The logic circuit 430 receives the first mode signal PMS1 through the first mode detecting node N1 and receives the second mode signal PMS2 through the second mode detecting node N2.

In the embodiment, during a process of assembling the electronic device 300, it is already known that the logic chip 400 is coupled to the connection port 320 having the I²C interface function. Therefore, corresponding settings may be configured for pins 1 to 16 of the logic chip 400. The first mode detecting node N1 is coupled to the pin 3 and the second mode detecting node N2 is coupled to the pin 4. The logic circuit 430 receives the first mode signal PMS1 through the pin 3 and receives the second mode PMS2 through the pin 4.

A first end of the first resistor R1 is coupled to the first mode detecting node N1, and a second end of the first resistor R1 is grounded. The voltage level at the first mode detecting node N1 is defined to be the first mode signal PMS1. A first end of the second resistor R2 is coupled to the second mode detecting node N2, and a second end of the second resistor R2 is also grounded. The voltage level at the second mode detecting node N2 is defined to be the second mode signal PMS2.

In the embodiment, the circuit modules Z1 to Z5 are circuit structures respectively having different functions. For example, the circuit modules Z1 to Z5 may be a fuse control circuit, a buffer circuit, a general-purpose input/output (GIPO), an I²C level shifter, or an electrostatic discharge (ESD) circuit, etc. The invention does not intend to limit the number and the functions of the circuit modules.

In the embodiment, in order to correspond to the connection port 320 having the I²C interface function, the pins 3 and 4 of the logic chip 400 are set to be open circuit. In other words, when the logic chip 400 is coupled to the connection port 320, the first mode signal PMS1 and the second mode signal PMS2 are at a first voltage level (i.e., low level). In other words, in this embodiment, the voltage levels of the first mode signal PMS1 and the second mode signal PMS2 can be determined according to whether or not the first resistor R1 and the second resistor R2 are coupled to the reference voltage VCCA.

When the logic circuit 430 detects that the first mode signal PMS1 and the second mode signal PMS2 are at the first voltage level, the circuit module Z3 and the circuit module Z4 are enabled by the logic circuit 430, and the circuit module Z1, the circuit module Z2 and the circuit module Z5 are disabled by the logic circuit 430 (in FIG. 4, the disabled circuit modules are omitted), thereby forming an equivalent circuit 440 corresponding to the I²C interface mode. In this way, the logic chip 400 is available for I²C communication.

Similarly, in another embodiment, when the logic chip 400 is coupled to the connection port 300 having the CRT interface function, the first mode detecting node N1 and the second mode detecting node N2 are connected to the reference voltage VCCA. Therefore, the first mode signal PMS1 and the second mode signal PMS2 are at a second voltage level (i.e., high level). According to the voltage levels of the first mode signal PMS1 and the second mode signal PMS2, the circuit modes Z1 to Z3 and Z5 are enabled by the logic circuit 430, and the circuit mode Z4 is disabled by the logic circuit 430. In this way, the logic chip 400 may operate in the CRT interface mode.

In another embodiment, when the logic chip 400 is coupled to the connection port 340 having the DP interface function, the first mode detecting node N1 is open circuit, and the second mode detecting node N2 is connected to the reference voltage VCCA. Therefore, the first mode signal PMS1 is at the first voltage level (i.e., low level) and the second mode signal PMS2 is at the second voltage level (i.e., high level). The circuit module Z1, the circuit module Z3, the circuit module Z4 and the circuit module Z5 are enabled by the logic circuit 430, and the circuit module Z2 is disabled by the logic circuit 430. In this way, the logic chip 400 may operate in the DP interface mode.

In another embodiment, when the logic chip 400 is coupled to the connection port 350 having the HDMI interface function, the first mode detecting node N1 is connected to the reference voltage VCCA, and the second mode detecting node N2 is open circuit. Therefore, the first mode signal PMS1 is at the second voltage level (i.e., high level) and the second mode signal PMS2 is at the first voltage level (i.e., low level). The circuit module Z1, the circuit module Z3, the circuit module Z4 and the circuit module Z5 are enabled by the logic circuit 430, and the circuit module Z2 is disabled by the logic circuit 430. In this way, the logic chip 400 may operate in the HDMI interface mode.

As the types of the connection port to which the logic chip 400 is coupled may differ, the manufacturer may input the corresponding setting for the input/output pins into the logic chip 400 during the manufacturing/assembling process. Specifically, as the types of the connection port differ, the pins connected for inputting and outputting may also differ. People skilled in the art may modify the embodiments according to common knowledge and practical needs, and details will not be reiterated in the following. Therefore, even if the same circuit modules are enabled by the logic circuit 430, the equivalent circuits formed thereby inside the logic chip 400 may differ as the connected pins differ. Therefore, different interface modes are rendered to allow the logic chip 400 to communicate with various types of connection ports.

In other words, the internal circuit design of the logic chip 400 integrates the circuits for various types of communication interfaces. During assembling, the manufacturer may configure the pins of the logic chip 400 in advance according to the types of the connection ports to be coupled, so as to determine the predetermined mode signal PMS. Therefore, the logic chip 400 may operate in the interface mode corresponding to the connection port according to the predetermined mode signal PMS. In addition, when the connection port to which the logic chip 400 is connected remains the same, the predetermined mode signal PMS also remains the same. For example, in the embodiment of FIG. 4, the logic chip 400 generates different predetermined mode signals PMS according to whether or not the pins 3 and 4 are open circuits or are coupled to the reference voltage and determines to enable or disable some of the circuit modules according to the predetermined mode signal PMS, so as to operate in the corresponding interface mode. Therefore, the processor 310 can communicate with different types of connection ports and peripheral devices by using the same logic chip 400.

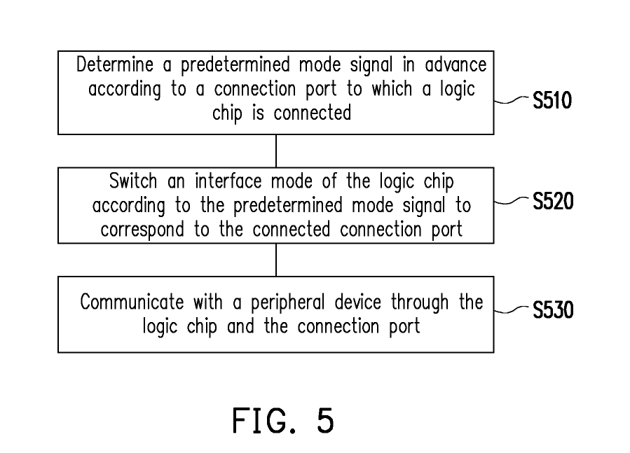

FIG. 5 is a flowchart illustrating a communication method of a logic chip according to an embodiment of the invention. The communication method of the logic chip shown in FIG. 5 is suitable for the electronic device 300 and the logic chip 400 shown in FIGS. 2 to 4.

At Step S510, the predetermined mode signal PMS is determined in advance according to the connection port (e.g., one of the connection ports 320, 330, 340, and 350) to which the logic chip 400 is connected. At Step S520, the logic circuit 430 may make the logic chip 400 operate in the interface mode corresponding to the connected connection port among the multiple interface modes according to the predetermined mode signal PMS. At Step S530, when the logic chip 400 operates in the corresponding interface mode, the processor 310 may communicate with the peripheral device through the logic chip 400 and the connection port. The communicating operation between the processor 310 and the peripheral device is carried out by the logic circuit 430.

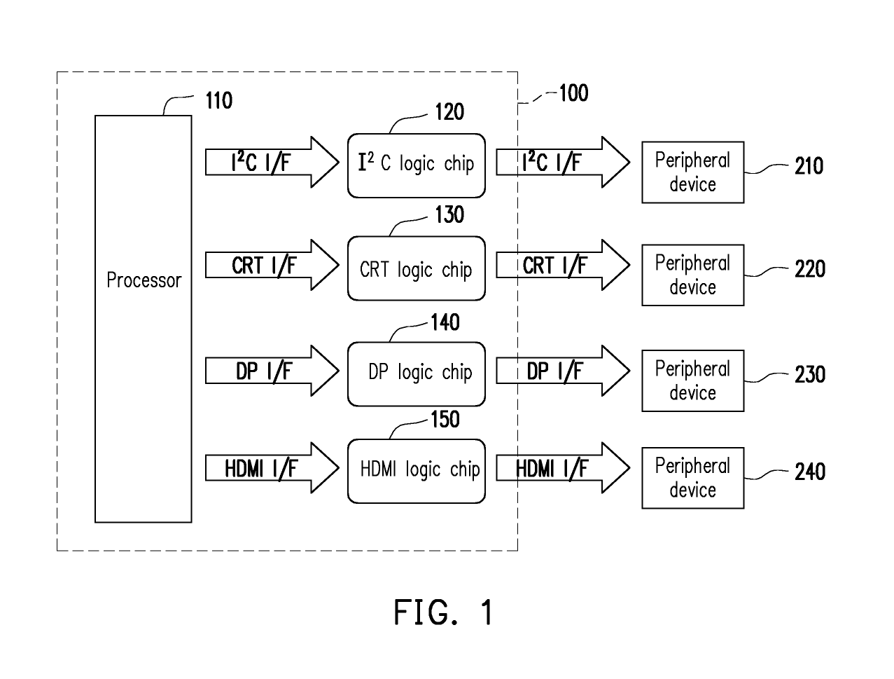

Implementing details of the communication method according to the embodiment of the invention are already described sufficiently in the embodiments described with reference to FIGS. 1 to 4. Therefore, details in this regard will not be reiterated in the following.

In view of the foregoing, in the electronic device, the logic chip and the communication method of the logic chip according to the embodiments of the invention, wherein the electronic device has the logic chip coupled between the processor and the connection port, the predetermined mode signal is determined in advance according to the communication type of the connected connection port, and the logic chip may operate in one of the interface modes according to the predetermined mode signal. Therefore, with the electronic device according to the embodiments of the invention, the same logic chip may be used to electrically connect the connection ports with different communication protocols.

It will be apparent to those skilled in the art that various modifications and variations can be made to the structure of the invention without departing from the scope or spirit of the invention. In view of the foregoing, it is intended that the invention cover modifications and variations of this invention provided they fall within the scope of the following claims and their equivalents.

What is claimed is:

1. An electronic device, electrically connected to a peripheral device, the electronic device comprising:
a connection port, configured to be coupled to the peripheral device;
a processor, coupled to the connection port; and
a logic chip, having a plurality of interface modes, the logic chip comprising:
a first communication interface, coupled to the processor;
a second communication interface, coupled to the connection port; and
a logic circuit, coupled between the first communication interface and the second communication interface and making the logic chip operate in one of the interface modes corresponding to the connection port according to a predetermined mode signal,
wherein the processor communicates with the peripheral device through the logic chip operating in the interface mode and the connection port.

2. The electronic device as claimed in claim 1, wherein the logic chip further comprises:
a plurality of circuit modules, coupled to the logic circuit, the first communication interface, and the second communication interface,
wherein the circuit modules are individually enabled or disabled by the logic circuit according to the predetermined mode signal to form one of the interface modes.

3. The electronic device as claimed in claim 1, wherein the predetermined mode signal is determined in advance according to the connection port to which the logic chip is connected, and when the connection port to which the logic chip is connected remains the same, the predetermined mode signal remains the same.

4. The electronic device as claimed in claim 1, wherein the logic chip further comprises a first mode detecting node and a second mode detecting node, and the predetermined mode signal comprises a first mode signal and a second mode signal, wherein the logic circuit receives the first mode signal through the first mode detecting node and receives the second mode signal through the second mode detecting node.

5. The electronic device as claimed in claim 4, wherein the interface modes comprise a first interface mode, a second interface mode, a third interface mode, and a fourth interface mode,
wherein when the first mode signal is at a first voltage level and the second mode signal is at the first voltage level, the logic chip operates in the first interface mode,
when the first mode signal is at a second voltage level and the second mode signal is at the second voltage level, the logic chip operates in the second interface mode,
when the first mode signal is at the first voltage level and the second mode signal is at the second voltage level, the logic chip operates in the third interface mode, and
when the first mode signal is at the second voltage level and the second mode signal is at the first voltage level, the logic chip operates in the fourth interface mode.

6. The electronic device as claimed in claim 4, wherein the logic chip further comprises:
a first resistor and a second resistor, wherein a first end of the first resistor is coupled to the first mode detecting node, a first end of the second resistor is coupled to the second mode detecting node, and a second end of the first resistor and a second end of the second resistor are coupled to a ground voltage,
wherein the voltage levels of the first mode signal and the second mode signal are determined according to whether or not the first resistor and the second resistor are coupled to a reference voltage.

7. The electronic device as claimed in claim 1, wherein the interface modes comprise at least one of a high definition multimedia interface (HDMI) mode, a display port (DP) mode, a cathode ray tube (CRT) mode, and an inter-integrated circuit (I²C) bus mode.

8. The electronic device as claimed in claim 1, wherein the logic circuit further comprises:
a memory, coupled to the logic circuit and storing a parameter reference table, wherein the parameter reference table records a corresponding relationship between the predetermined mode signal and the interface modes,
wherein the logic circuit determines the interface mode corresponding to the connection port through the parameter reference table according to the predetermined mode signal.

9. A logic chip, suitable for an electronic device, wherein the electronic device comprises a processor and a connection port, the connection port is electrically connected to a peripheral device, and the logic chip comprises:
a first communication interface, coupled to the processor;
a second communication interface, coupled to the connection port; and
a logic circuit, coupled between the first communication interface and the second communication interface, wherein the logic chip has a plurality of interface modes, and the logic circuit makes the logic chip operate in one of the interface modes corresponding to the connection port according to a predetermined mode signal,
wherein the processor communicates with the peripheral device through the logic chip operating in the interface mode and the connection port.

10. A communication method of a logic chip, suitable for an electronic device, wherein the electronic device comprises a connection port, a processor and a logic chip, the connection port is electrically connected to a peripheral device and the logic chip, the logic chip is coupled to the processor and has a plurality of interface modes and a logic circuit, and the communication method comprises:
determining a predetermined mode signal in advance according to the connection port to which the logic chip is connected; and
making the logic chip operate in one interface mode of the interface modes corresponding to the connection port according to the predetermined mode signal,
wherein the processor communicates with the peripheral device through the logic chip operating in the interface mode and the connection port.

11. The communication method as claimed in claim 10, wherein the logic chip comprises a plurality of circuit modules, and the circuit modules are individually enabled or disabled by the logic circuit logic chip according to the predetermined mode signal to form one of the interface modes.

12. The communication method as claimed in claim 10, wherein when the connection port to which the logic chip is connected remains the same, the predetermined mode signal remains the same.

13. The communication method as claimed in claim 10, wherein the predetermined mode signal comprises a first mode signal and a second mode signal, and the logic circuit receives the first mode signal through a first mode detecting node and the logic circuit receives the second mode signal through a second mode detecting node.

14. The communication method as claimed in claim 13, wherein the interface modes comprise a first interface mode, a second interface mode, a third interface mode, and a fourth interface mode,
wherein when the first mode signal is at a first voltage level and the second mode signal is at the first voltage level, the logic chip operates in the first interface mode,
when the first mode signal is at a second voltage level and the second mode signal is at the second voltage level, the logic chip operates in the second interface mode,
when the first mode signal is at the first voltage level and the second mode signal is at the second voltage level, the logic chip operates in the third interface mode, and
when the first mode signal is at the second voltage level and the second mode signal is at the first voltage level, the logic chip operates in the fourth interface mode.

15. The communication method as claimed in claim 10, wherein the interface modes comprise at least one of a high definition multimedia interface (HDMI) mode, a display port (DP) mode, a cathode ray tube (CRT) mode, and an inter-integrated circuit (I²C) bus mode.
